(19) United States
(12) Patent Application Publication
(10) Pub. No.: US 2023/0318585 A1
(43) Pub. Date: Oct. 5, 2023

(54) DIVIDER AND DIVIDER CONTROL METHOD

(71) Applicant: LAPIS Technology Co., Ltd., Yokohama (JP)

(72) Inventor: Toru YOSHIOKA, Yokohama (JP)

(73) Assignee: LAPIS Technology Co., Ltd., Yokohama (JP)

(21) Appl. No.: 18/190,126

(22) Filed: Mar. 27, 2023

(30) Foreign Application Priority Data
Mar. 30, 2022 (JP) 2022-057754

(51) Int. Cl. H03K 3/037; H03K 3/017

(52) U.S. Cl. CPC H03K 3/0372; H03K 3/017; H03K 19/20

(57) ABSTRACT

A divider includes: a divider circuit including a plurality of flip-flops and configured to divide an input first clock signal at a division ratio in accordance with a control signal; and an adjustment circuit configured to adjust a duty ratio of an input second clock signal and outputs the first clock signal. The adjustment circuit performs adjustment so that the duty ratio of the first clock signal increases in a case where the flip-flops are positive edge triggers and the duty ratio of the first clock signal decreases in a case where the flipflops are negative edge triggers.

### CROSS-REFERENCE TO RELATED APPLICATION

This application claims priority under 35 USC 119 from Japanese Patent application No. 2022-057754 filed on Mar. 30, 2022, the disclosure of which is incorporated by reference herein.

### BACKGROUND

### Technical Field

The disclosure relates to a divider and a divider control method.

### Description of Related Art

In recent years, high performance and multi-functionality of wireless communication LSIs have progressed. Phase locked loops (PLLs) are used to generate frequencies used for transmission and reception in wireless communication LSIs. Divider circuits are used for various purposes in wireless LSIs. Inside PLLs, PLL output signals are divided until the same frequencies as reference signals of crystal oscillators are obtained, and the frequencies are used for comparing phases. To support various frequency bands and standards, output signals of PLLs are divided at appropriate division ratios and are delivered to transmission and reception circuits. In recent wireless communication LSIs, it is necessary to divide signals of a few GHz.

As a technology related to a divider, for example, Japanese Patent Laid-Open No. H6-258465 discloses a variable divider circuit including a first shift register which includes flip-flops in m stages and sequentially shifts input signals based on a clock signal, a second shift register which includes flip-flops in n (where n≤m) stages, to which output signals of the first shift register are input based on a clock signal, and which sequentially shifts the output signals, a first gate circuit to which the output signals of the first shift register are input and that is opened or closed in accordance with a first operation mode signal and outputs a first feedback signal, and a second gate circuit to which the output signals of the second shift register are input and which is opened or closed in accordance with the first feedback signal and feeds the output signals back to an input side of the first shift register. The clock signal is divided at one of a division ratio of 1/(2m+n) or a division ratio of 1/{2(m+n)} to be output from the second shift register.

However, in the divider that has the foregoing configuration, a high-speed operation is difficult. In particular, there is concern of an operation frequency of the divider deteriorating due to an influence of signal propagation delay. In other words, an operation condition of the divider is constrained in accordance with a delay time specific to a divider circuit, such as transition delay or the like.

### SUMMARY

The disclosure provides a divider and a divider control method.

According to an aspect of the disclosure, a divider includes: a divider circuit including a plurality of flip-flops and configured to divide a first clock signal that is input at a division ratio in accordance with a control signal; and an adjustment circuit configured to adjust a duty ratio of a second clock signal that is and output the first clock signal. The adjustment circuit performs adjustment so that a duty ratio of the first clock signal increases in a case where the flip-flops are positive edge triggers and the duty ratio of the first clock signal decreases in a case where the flip-flops are negative edge triggers.

According to another aspect of the disclosure, a divider control method for a divider including a divider circuit that includes a plurality of flip-flops and divides an input first clock signal at a division ratio in accordance with a control signal and an adjustment circuit that adjusts a duty ratio of an input second clock signal and outputs the first clock signal is a method including: inputting the control signal for designating a division ratio to the divider circuit; and controlling the adjustment circuit to perform adjustment so that a duty ratio of the first clock signal increases in a case where the flip-flops are positive edge triggers and the duty ratio of the first clock signal decreases in a case where the flip-flops are negative edge triggers.

According to the disclosure, it is possible to operate stably even in a high-speed operation.

### BRIEF DESCRIPTION OF THE DRAWINGS

FIG. 1 is a circuit diagram illustrating an exemplary configuration of a divider according to a first embodiment of the disclosure.

FIG. 2 is a circuit diagram illustrating an exemplary configuration of a duty ratio adjustment circuit.

FIG. 3 is a timing chart illustrating an adjustment principle of the duty ratio adjustment circuit illustrated in FIG. 2.

FIG. 4 is a timing chart illustrating an operation of the divider illustrated in FIG. 1.

FIG. 5 is a circuit diagram illustrating an example of a detailed circuit configuration of the divider illustrated in FIG. 1.

FIG. 6 is a timing chart illustrating transition delay.

FIG. 7 is a circuit diagram illustrating an exemplary configuration of a duty ratio adjustment circuit according to a second embodiment.

FIG. 8 is a schematic diagram illustrating the duty ratio adjustment circuit illustrated in FIG. 7.

FIG. 9 is a timing chart illustrating an adjustment principle of the duty ratio adjustment circuit illustrated in FIG. 7.

### DESCRIPTION OF THE EMBODIMENTS

Hereinafter, examples of embodiments of the disclosure will be described in detail with reference to the drawings.

### First Embodiment

### Circuit Configuration

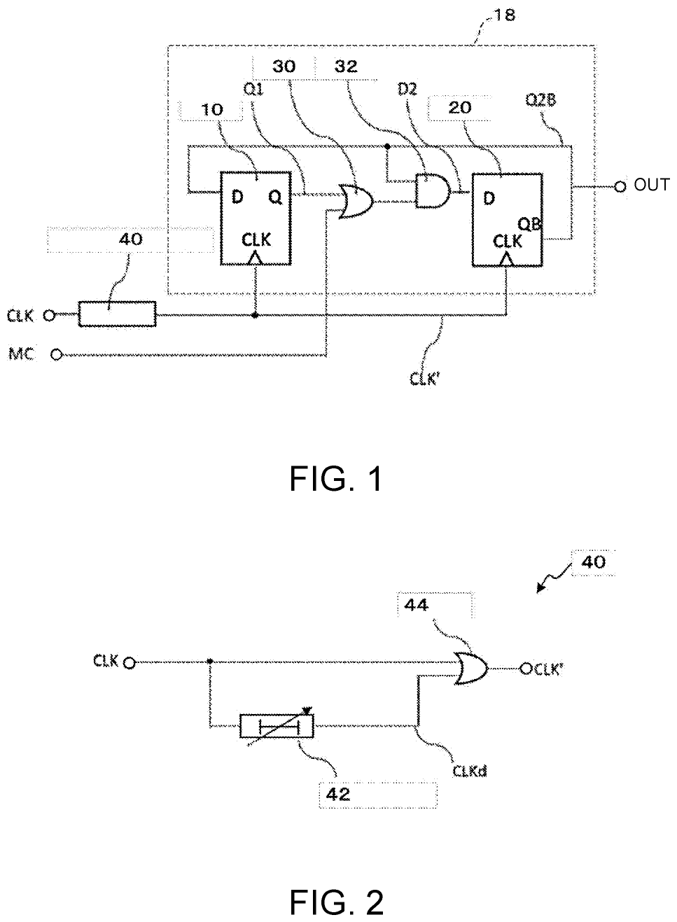

FIG. 1 is a circuit diagram illustrating an exemplary configuration of a divider according to a first embodiment of the disclosure.

As illustrated in FIG. 1, the divider includes a divider circuit 18 and a duty ratio adjustment circuit 40 provided at a front stage of the divider circuit 18. The divider circuit 18 includes a D flip-flop 10, a D flip-flop 20, an OR circuit 30, and an AND circuit 32.

The divider can switch a division ratio in accordance with a control signal MC from a control circuit (not illustrated) between 2 or 3 and divides a clock input to CLK terminals into 2 or 3 to output the clock from an output terminal. The duty ratio adjustment circuit 40 is controlled by the control circuit (not illustrated).

The D flip-flop 10 detects a logical value input to a D terminal while a clock signal CLK′ input to the CLK terminal is at a high level (hereinafter abbreviated to “H”) and outputs a logical value detected at a fall of the clock signal CLK′ from a Q terminal. An output signal Q1 is input to the OR circuit 30.

The D flip-flop 20 detects a logical value input to a D terminal while a clock signal CLK′ input to the CLK terminal is at “H” and outputs an inverted logical value of the signal detected at the fall of the clock signal CLK′ from a QB terminal. An output signal Q2B is input as a feedback signal to the D flip-flop 10 and the AND circuit 32. The output signal Q2B is output from an output terminal of the divider.

The OR circuit 30 to which the output signal Q1 of the D flip-flop 10 and the control signal MC are input outputs a signal indicating a logical sum of logical values of the two input signals. Specifically, when any of the logical values of the input two input signals is at a low level (hereinafter abbreviated to “L”), “L” is output. In the case of other inputs, “H” is output. The output signal is input to the AND circuit 32.

The AND circuit 32 to which the output signal Q2B which is a feedback signal from the D flip-flop 20 and the output signal of the OR circuit 30 are input outputs a signal indicating a logical product of logical values of the two input signals. Specifically, when any of the logical values of the input two input signals is at “H,” “H” is output. In the case of other inputs, “L” is output. An output signal D2 is input to the D flip-flop 20.

The duty ratio adjustment circuit 40 is a circuit that has a function of adjusting a duty ratio of the input clock signal CLK and outputs the clock signal CLK′ of which the duty ratio has been adjusted. The output clock signal CLK′ is input to the CLK terminals of the D flip-flops 10 and 20. Here, the duty ratio is a ratio (%) of a pulse width (a section of “H”) to a pulse period.

Under the control of a control circuit (not illustrated), the duty ratio adjustment circuit 40 performs adjustment so that the duty ratio increases in a case where the D flip-flops 10 and 20 are positive edge triggers operating in synchronization with a rise of the clock signal and the duty ratio decreases in a case where the D flip-flops 10 and 20 are negative edge triggers operating in synchronization with a fall of the clock signal. Here, since the D flip-flops 10 and 20 are the positive edge triggers, the duty ratio of the clock signal CLK′ is adjusted so that a section of “H” is longer than that of the clock signal CLK.

### Duty Ratio Adjustment Circuit

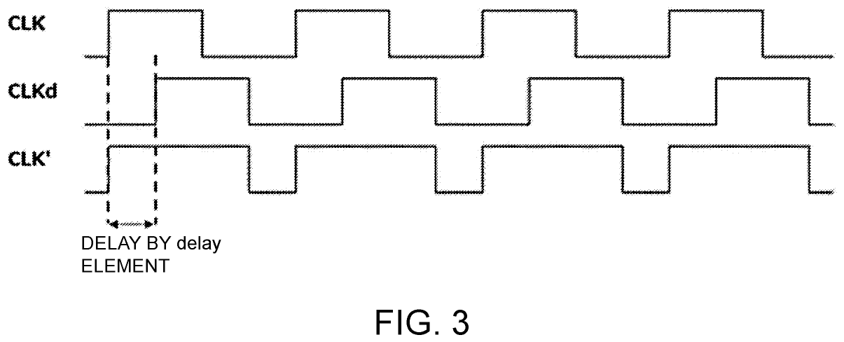

FIG. 2 is a circuit diagram illustrating an exemplary configuration of the duty ratio adjustment circuit 40. The duty ratio adjustment circuit 40 includes a delay element 42 and an OR circuit 44. The delay element 42 delays the input clock signal CLK and outputs a delayed clock signal CLKd. The OR circuit 44 outputs a logical sum of the two input signals, that is, outputs “L” in a case where any of the logical values of the clock signals CLK and CLKd is “L” and outputs “H” in the case of other inputs. As a result, as illustrated in FIG. 3, the duty ratio adjustment circuit 40 outputs the clock signal CLK′ in which a section of “H” is longer than that of the clock signal CLK.

### Dividing Operation

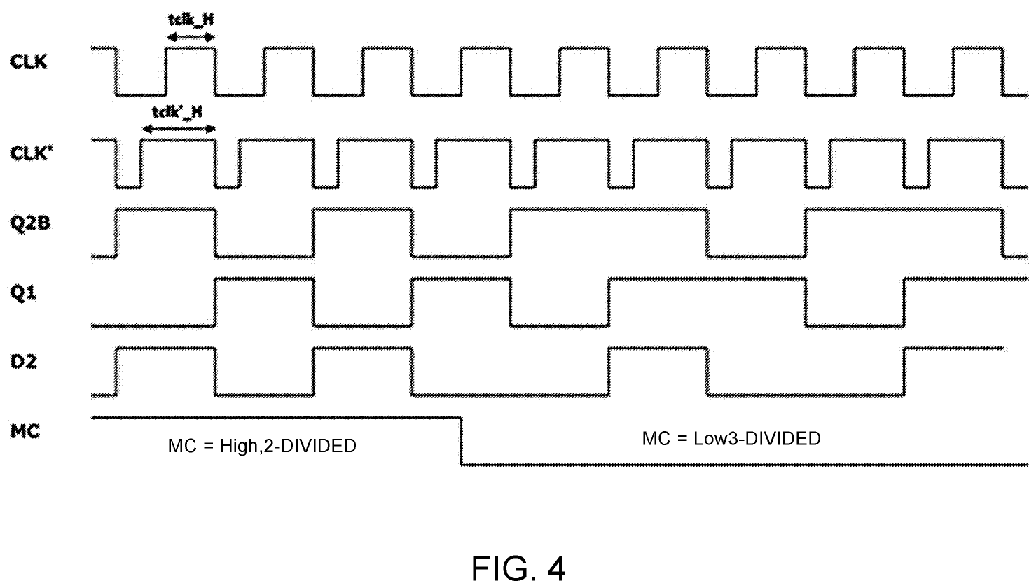

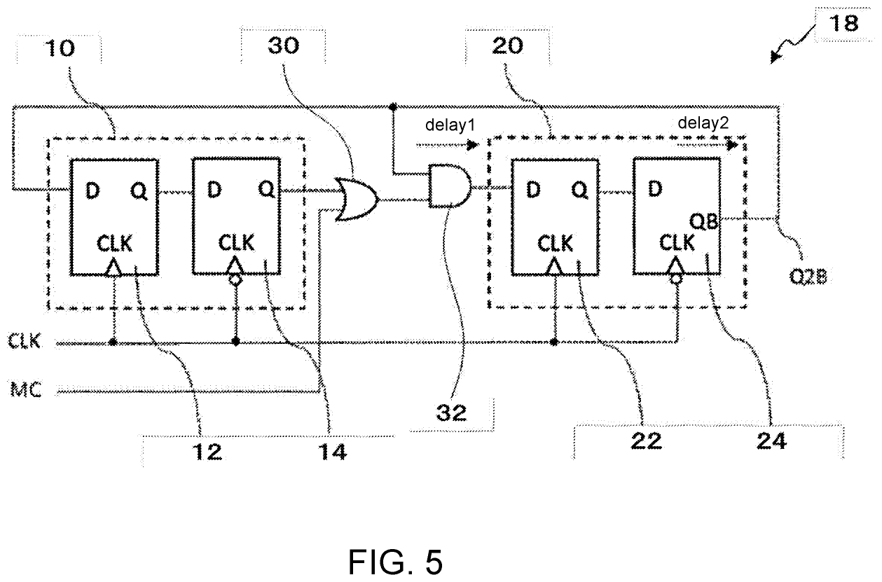

Next, an operation of the divider illustrated in FIG. 1 will be described with reference to a timing chart illustrated in FIG. 4. The timing chart shows timings of changes in the clock signal CLK′ after adjustment of the duty ratio, the output signal Q2B of the D flip-flop 20, the output signal Q1 of the D flip-flop 10, and the output signal D2 of the AND circuit 32. For reference, the clock signal CLK before adjustment of the duty ratio is also illustrated.

### 2-Dividing Operation

First, a 2-dividing operation when the control signal MC is at “H” will be described. When the control signal MC is at “H,” an output signal of the OR circuit 30 is fixed to “H” regardless of a value of the input signal Q1. The output signal D2 of the AND circuit 32 follows the output signal Q2B of the D flip-flop 20 since one input signal is fixed to “H.”

In an initial state, it is assumed that any of the output signal Q1 of the D flip-flop 10 and the output signal Q2B of the D flip-flop 20 is at “L.” Accordingly, the output signal D2 of the AND circuit 32 is at “L.”

First, when the clock signal CLK′ is at “H,” the D flip-flop 20 detects that the input signal D2 is at “L” and the output signal Q2B of the D flip-flop 20 transitions to “H” at a timing of a fall of the clock signal CLK′. Here, the output signal D2 of the AND circuit 32 enters “H.”

When the clock signal CLK′ enters “H” in the second time, the D flip-flop 20 detects that the input signal D2 is at “H” and the output signal Q2B enters “L” at a timing of a fall of the clock signal CLK′. At this time, the output signal D2 of the AND circuit 32 is at “L” and has the same logic as that of the initial state.

By repeating this operation, it is possible to obtain the 2-divided signals from the output signal Q2B.

### 3-Dividing Operation

Next, a 3-dividing operation when the control signal MC is at “L” will be described.

In an initial state, it is assumed that the output signal Q1 of the D flip-flop 10 is at “H” and the output signal Q2B of the D flip-flop 20 is at “L.” An output signal of the OR circuit 30 follows a value of the output signal Q1 of the D flip-flop 10. At this time, the output signal D2 of the AND circuit 32 is at “L.”

First, when the clock signal CLK′ enters “H,” the D flip-flop 10 detects “L” and the D flip-flop 20 detects “L.” Therefore, at a timing of a fall of the clock signal CLK′, the output signal Q1 of the D flip-flop 10 transitions to “L” and the output signal Q2B of the D flip-flop 20 transitions to “H.” At this time, the output signal D2 of the AND circuit 32 remains at “L.”

When the clock signal CLK′ enters “H” in the second time, the D flip-flop 10 detects “H” and the D flip-flop 20 detects “L.” Therefore, at a timing of a fall of the clock signal CLK′, the output signal Q1 of the D flip-flop 10 transitions to “H.” The output signal Q2B of the D flip-flop 20 remains at “H.” At this time, the output signal D2 of the AND circuit 32 transitions to “H.”

When the clock signal CLK′ enters “H” in the third time, the D flip-flop 10 detects “H” and the D flip-flop 20 detects “H.” Therefore, at a timing of a fall of the clock signal CLK′, the output signal Q2B of the D flip-flop 20 transitions to “L.” The output signal D2 of the AND circuit 32 transitions to “L” and matches the initial state.

In this way, at each clock, the state transitions are repeated in the 3-dividing operation as (Q1, Q2B)=(H, L), (L, H), (H, H), (H, L),

### Alleviation of Constraints

Next, a detailed configuration of the divider circuit 18 will be described.

FIG. 5 is a circuit diagram illustrating an example of a detailed circuit configuration of the divider circuit 18 illustrated in FIG. 1. As illustrated in FIG. 5, each of the D flip-flops 10 and 20 is a master-slave flip-flop. The D flip-flop 10 includes a master-side latch 12 and a slave-side latch 14.

The master-side latch 12 detects a signal input to the D terminal while a signal input to the CLK terminal is at “H,” and outputs the detected signal from the Q terminal. The master-side latch 12 maintains an output state while the signal input to the CLK terminal is at “L.” The slave-side latch 14 detects a signal input to the D terminal while the signal input to the CLK terminal is at “L,” and outputs the detected signal from the Q terminal. The slave-side latch 14 maintains an output state while the signal input to the CLK terminal is at “H.”

Similarly, the D flip-flop 20 includes a master-side latch 22 and a slave-side latch 24. The master-side latch 22 detects a signal input to the D terminal while a signal input to the CLK terminal is at “H,” and outputs the detected signal from the Q terminal. The master-side latch 22 maintains an output state while the signal input to the CLK terminal is at “L.” The slave-side latch 24 detects a signal input to the D terminal while the signal input to the CLK terminal is at “L,” and outputs an inverted logical value of the detected signal from the QB terminal. The slave-side latch 24 maintains an output state while the signal input to the CLK terminal is at “H.”

In the divider circuit that has the foregoing structure, a value of the output signal Q2B of the D flip-flop 20 is delayed until propagation to the latch 22. An operation frequency of the divider is constrained in accordance with the transition delay time.

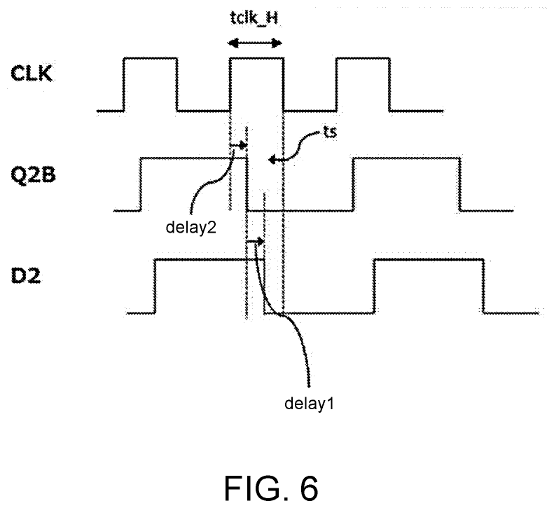

FIG. 6 is a timing chart illustrating transition delay. When a case in which the clock signal CLK before adjustment of the duty ratio is input, it is assumed that delay1 is a transition delay time of the AND circuit 32 and delay2 is a transition delay time of the latch 24. The latch 24 delays a signal by delay2 from a timing of a rise of the clock signal CLK to output the output signal Q2B. It is necessary for the D flip-flop 20 to drive an input capacity of a circuit such as the D-flip-flop 10 or the AND circuit 32 connected to a next stage, and thus the delay time delay2 until propagation of the output signal Q2B is increased.

The AND circuit 32 further delays the signal by delay1 from an output of the output signal Q2B to output the output signal D2. In order for the latch 22 to correctly detect a logical value at a timing of a fall of the clock, a logical value of the input signal D2 of the latch 22 is necessarily confirmed at a time earlier by ts than the timing of the fall. The time ts is called a setup time of the latch 22.

Accordingly, until a timing at which the clock signal CLK rises to “H” and then falls subsequently, a value of the output signal Q2B necessarily propagates to the latch 22. Here, when tclk_{H} is a time width of “H” of the clock signal CLK, as understood from FIG. 6, it is necessary to satisfy a condition shown in the following Expression (1) so that the divider normally operates. In other words, when the condition shown in the following Expression (1) is not satisfied, the divider may become inoperative, which results in a considerable reduction in an operation speed.

[Math. 1]

tclk_{H}>dely1+delay2+ts (1)

As described above, the duty ratio adjustment circuit 40 outputs the clock signal CLK′ in which a section of “H” is longer than that of the clock signal CLK. When tclk′_{H} is a time width of “H” of the clock signal CLK′, the following relationship is established.

[Math. 2]

tclk′_{H}>tclk_{H} (2)

Accordingly, when the clock signal CLK′ after adjustment of the duty ratio is input, it is necessary to satisfy a condition shown in the following Expression (3).

[Math. 3]

tclk′_{H}>dely1+delay2+ts (3)

As understood from the foregoing Expressions (1) to (3), an operation condition of the divider is alleviated by using the clock signal CLK′ after adjustment of the duty ratio. Therefore, a high-speed operation can be performed compared to a case where the clock signal CLK before adjustment of the duty ratio is used.

For example, when the setup time ts is 50 picoseconds (ps), delay1 is 30 ps, and delay2 is 20 ps, a sum value is 100 ps. In this case, the divider becomes inoperative at 5 GHz. This is because when a period of a 5 GHz signal is 200 ps and a duty ratio is 50%, tclk_{H} is 100 ps, and thus the foregoing Expression (1) cannot be satisfied. On the other hand, when the duty ratio is 75%, tclk′_{H} is 150 ps. Then, since the foregoing Expression (3) is satisfied, an operation can be performed. In the embodiment, in consideration of the transition delay time or the setup time, the duty ratio is adjusted so that tclk′_{H} satisfies the foregoing Expression (3).

A state of the D flip-flop transitions at a timing of a fall of the clock signal. Therefore, even when the duty ratio of the clock signal is changed, an obtainable divided signal is changeless. In the clock signal CLK′ after adjustment of the duty ratio, a section of “L” becomes short.

However, the transition delay and the setup time of the signal between the latches of the D flip-flops may satisfy the foregoing Expression (3). A capacity load between the latches can be designed to be small. Therefore, an influence of an operation speed can be ignored.

As described in detail above, in the first embodiment, by providing the duty ratio adjustment circuit 40 adjusting the duty ratio of the clock signal input to the divider circuit 18, it is possible to alleviate the operation condition of the divider constrained due to transition delay or the like, and thus the divider can stably operate even at a high-speed operation.

### Second Embodiment

A second embodiment is similar to the first embodiment except that a configuration of a duty ratio adjustment circuit is different. Therefore, only differences will be described.

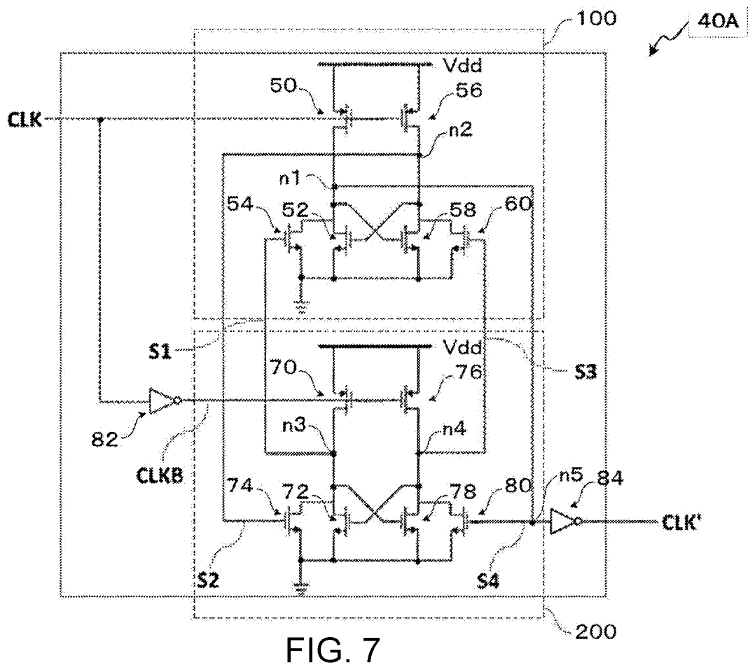

FIG. 7 is a circuit diagram illustrating an exemplary configuration of a duty ratio adjustment circuit according to the second embodiment. A duty ratio adjustment circuit 40A illustrated in FIG. 7 is another divider circuit. That is, in the second embodiment, a different divider circuit is connected to a front stage of the divider circuit and the divider circuit at the front stage serves as a duty ratio adjustment circuit 40A.

The duty ratio adjustment circuit 40A includes NOT circuits 82 and 84, PMOSs 50, 56, 70, and 76, and NMOSs 52, 54, 58, 60, 72, 74, 78, and 80.

A source terminal of the PMOS 50 is connected to a power potential Vdd, a drain terminal is connected to a drain terminal of the NMOS 52, and a source terminal of the NMOS 52 is grounded, so that an inverter circuit is configured. Similarly, the PMOS 56 and the NMOS 58 also configure an inverter circuit. The NMOS 54 is connected to the NMOS 52 in parallel and the NMOS 60 is connected to the NMOS 58 in parallel. The two inverter circuits are cross-coupled to configure a master-side latch 100. Similarly, the PMOSs 70 and 76 and the NMOSs 72, 74, 78, and 80 configure a slave-side latch 200.

A node n1 between the PMOS 50 and the NMOS 52 of the master-side latch 100 is connected to a gate terminal of the NMOS 78 of the slave-side latch 200 via a node n5. Similarly, a node n2 is connected to a gate terminal of the NMOS 74. A node n3 between the PMOS 70 and the NMOS 72 of the slave-side latch 200 is connected to a gate terminal of the NMOS 54 of the master-side latch 100. Similarly, a node n4 is connected to a gate terminal of the NMOS 58.

An input terminal is connected to gate terminals of the PMOSs 50 and 56 and is connected to gate terminals of the PMOSs 70 and 76 via the NOT circuit 82. The node n5 is connected to an output terminal via the NOT circuit 84. The circuit illustrated in FIG. 7 functioning as a 2-dividing circuit divides the clock signal CLK input from the input terminal into 2 and outputs the clock signal CLK′ with a duty ratio of 75% from the output terminal.

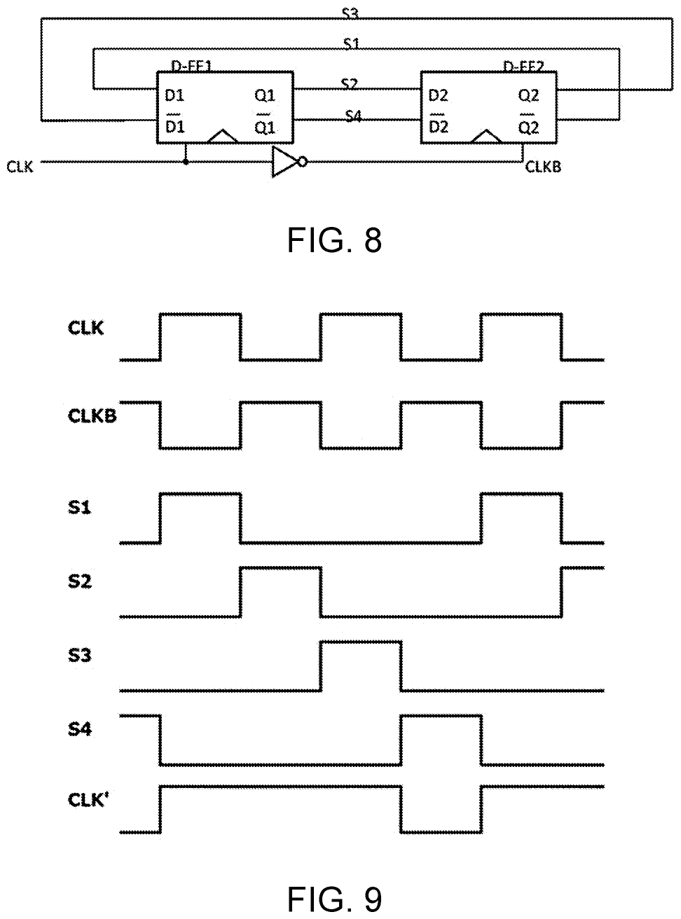

FIG. 8 is a schematic diagram illustrating the duty ratio adjustment circuit 40A illustrated in FIG. 7. As illustrated in FIG. 8, the duty ratio adjustment circuit 40A includes a D flip-flop (D-FF1) corresponding to the master-side latch 100 and a D flip-flop (D-FF2) corresponding to the slave-side latch 200. Here, each signal can be defined as follows.

A signal 51: an input signal of the master-side latch/an inverted output signal of the slave-side latch.

A signal S2: an output signal of the master-side latch/an input signal of the slave-side latch.

A signal S3: an inverted input signal of the master-side latch/an output signal of the slave-side latch.

A signal S4: an inverted output signal of the master-side latch/an inverted input signal of the slave-side latch.

A signal CLKB: an inverted signal of the clock signal CLK.

FIG. 9 is a timing chart illustrating an adjustment principle of the duty ratio adjustment circuit illustrated in FIG. 7. When the input clock signal CLK is at “H,” the PMOSs 50 and 56 are turned off, the master-side latch 100 detects an input signal while the clock signal CLK is at “H,” the PMOSs 70 and 76 are turned on, and the slave-side latch 200 maintains an output state. Conversely, when the input clock signal CLK is at “L,” the slave-side latch 200 conversely detects an input signal while the clock signal CLKB is at “H,” and the master-side latch 100 maintains an output state.

In an initial state, it is assumed that the signals S1, S2, and S3 are at “L” and the signal S4 is at “H.”

First, when the clock signal CLK is at “H,” the master-side latch 100 detects that the input signal S1 is at “L” and the inverted input signal S3 is at “L.” On the other hand, the slave-side latch 200 maintains the output signal S3 at “L” in accordance with the input signal S2 entering “L” at a timing of a fall of the clock signal CLKB, causes the inverted output signal S1 to transition to “H” in accordance with the inverted input signal S4 entering “H,” and maintains the output.

At a timing of a fall of the first clock signal CLK, that is, at a time at which the first clock signal CLKB enters “H,” the slave-side latch 200 detects that the input signal S2 is at “L” and the inverted input signal S4 is at “L.” On the other hand, the master-side latch 100 causes the output signal S2 to transition to “H” in accordance with the input signal S1 entering “L,” maintains the inverted output signal S4 at “L” in accordance with the input signal S3 entering “L,” and maintains the output.

When the clock signal CLK enters “H” in the second time, the master-side latch 100 detects that the input signal S1 is at “L” and the inverted input signal S3 is at the “L.” On the other hand, the slave-side latch 200 causes the output signal S3 to transition to “H” in accordance with the input signal S2 entering “H” at a timing of a fall of the clock signal CLKB, maintains the inverted output signal Si at the “L” in accordance with the inverted input signal S4 entering “L,” and maintains the output.

At a timing of a fall of the second clock signal CLK, that is, at a time at which the second clock signal CLKB enters “H,” the slave-side latch 200 detects that the input signal S2 is at “L” and the inverted input signal S4 is at “L.” On the other hand, the master-side latch 100 maintains the output signal S2 at “L” in accordance with the input signal S1 entering “L,” causes the inverted output signal S4 to transition to “H” in accordance with the input signal S3 entering “H,” and maintains the output. Then, the state turns to the initial state.

In this way, the master-side latch 100 and the slave-side latch 200 repeat the foregoing cycle at which the input detecting and output maintaining operations are alternately performed in accordance with switching of the clock signal. As a result, the clock signal CLK′ with a duty ratio of 75% is output as the inverted signal of the signal S4 from the output terminal of the circuit illustrated in FIG. 7.

According to the second embodiment, in addition to the obtained advantages similar to those of the first embodiment, the clock signal with a duty ratio of 50% or more can be generated with high accuracy compared to the duty ratio adjustment circuit according to the first embodiment in which the delay element is used. For example, in the circuit configuration of the duty ratio adjustment circuit 40A illustrated in FIG. 7, the clock signal CLK′ with the duty ratio of 75% can be generated with high accuracy.

### Modification Examples

The configurations of the divider circuit and the divider circuit control method described in the foregoing embodiments are exemplary. It is needless to say that the configurations may be changed within the scope of the disclosure without departing from the gist of the prevent disclosure.

In the foregoing first and second embodiments, the cases in which the D flip-flops are the positive edge triggers in which the logical values of the output signals are changed at the timing of the rise of the clock signal have been described. However, the D flip-flops may be negative edge triggers in which the logical values of the output signals are changed at the timing of a fall of the clock signal. In the case of the negative edge triggers, similar effects can be obtained by lengthening a section of “L” of an input clock signal.

In the foregoing first and second embodiments, the ⅔-divider circuits with the specific configurations have been described, but the present technology can be applied to a circuit such as ¾-divider circuit in which an operation frequency is constrained in accordance with similar operation conditions.

In the foregoing first and second embodiments, the duty ratio adjustment circuits with the specific configurations have been exemplified, but a configuration of a duty ratio adjustment circuit is not limited thereto. For example, by changing a phase of a clock signal and taking a logical sum of signals before the change in the phase, it is possible to adjust the duty ratio.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A divider comprising:
a divider circuit including a plurality of flip-flops and configured to divide a first clock signal that is input at a division ratio in accordance with a control signal; and
an adjustment circuit configured to adjust a duty ratio of a second clock signal that is input and output the first clock signal,
wherein the adjustment circuit performs adjustment so that a duty ratio of the first clock signal increases in a case where the flip-flops are positive edge triggers and the duty ratio of the first clock signal decreases in a case where the flip-flops are negative edge triggers.

2. The divider according to claim 1,
wherein the divider circuit includes
a first flip-flop which detects a logical value of a signal input while the first clock signal is at a high level, and outputs a signal indicating a logical value detected at a fall or a rise of the first clock signal,
a second flip-flop which detects the logical value of the signal input while the first clock signal is at the high level and outputs a signal indicating an inverted logical value of the logical value detected at the fall or the rise of the first clock signal,
an OR circuit to which an output signal of the first flip-flop and the control signal are input and which outputs a signal indicating a logical sum of logical values of the output signal of the first flip-flop and the control signal that are input, and
an AND circuit to which an output signal of the OR circuit and a feedback signal from the second flip-flop are input and which outputs a signal indicating a logical product of logical values of the output signal of the OR circuit and the feedback signal from the second flip-flop that are input to the second flip-flops, and
wherein the feedback signal from the second flip-flop is input to the first flip-flop.

3. The divider according to claim 2, wherein each of the first and second flip-flops is a master-slave flip-flop which includes a master-side latch and a slave-side latch.

4. The divider according to claim 3, wherein the adjustment circuit adjusts the duty ratio so that a time width of H of the first clock signal in the case where the flip-flops are the positive edge triggers or a time width of L of the first clock signal in the case where the flip-flops are the negative edge triggers is greater than a sum of a transition delay time of the AND circuit, a transition delay time of the slave-side latch of the second flip-flop, and a setup time of the slave-side latch of the second flip-flop.

5. The divider according to claim 1, wherein the adjustment circuit includes
a delay element which divides and delays a third clock signal that is input and outputs a delayed fourth clock signal, and
an OR circuit to which the third and fourth clock signals are input and takes a logical sum of logical values of the third and fourth clock signals that are input and outputs the first clock signal.

6. The divider according to claim 1, wherein the adjustment circuit is a master-slave divider that includes a master-side latch and a slave-side latch.

7. A divider control method for a divider including a divider circuit that includes a plurality of flip-flops and divides a first clock signal that is input at a division ratio in accordance with a control signal and an adjustment circuit that adjusts a duty ratio of a second clock signal that is input and outputs the first clock signal, the divider control method comprising:
inputting the control signal for designating a division ratio to the divider circuit: and
controlling the adjustment circuit to perform adjustment so that a duty ratio of the first clock signal increases in a case where the flip-flops are positive edge triggers and the duty ratio of the first clock signal decreases in a case where the flip-flops are negative edge triggers.

8. The divider according to claim 2, wherein the adjustment circuit includes
a delay element which divides and delays a third clock signal that is input and outputs a delayed fourth clock signal, and
an OR circuit to which the third and fourth clock signals are input and takes a logical sum of logical values of the third and fourth clock signals that are input and outputs the first clock signal.

9. The divider according to claim 3, wherein the adjustment circuit includes
a delay element which divides and delays a third clock signal that is input and outputs a delayed fourth clock signal, and
an OR circuit to which the third and fourth clock signals are input and takes a logical sum of logical values of the third and fourth clock signals that are input and outputs the first clock signal.

10. The divider according to claim 4, wherein the adjustment circuit includes
a delay element which divides and delays a third clock signal that is input and outputs a delayed fourth clock signal, and
an OR circuit to which the third and fourth clock signals are input and takes a logical sum of logical values of the third and fourth clock signals that are input and outputs the first clock signal.

11. The divider according to claim 2, wherein the adjustment circuit is a master-slave divider that includes a master-side latch and a slave-side latch.

12. The divider according to claim 3, wherein the adjustment circuit is a master-slave divider that includes a master-side latch and a slave-side latch.

13. The divider according to claim 4, wherein the adjustment circuit is a master-slave divider that includes a master-side latch and a slave-side latch.
